(19) United States
(12) Patent Application Publication
(10) Pub. No.: US 2025/0226355 A1
(43) Pub. Date: Jul. 10, 2025

(54) SEMICONDUCTOR DEVICE AND MANUFACTURING METHOD THEREOF

(71) Applicant: Powerchip Semiconductor Manufacturing Corporation, Hsinchu (TW)

(72) Inventors: Chun-Lin Lu, Hsinchu City (TW); Yung-Hsiang Chang, Hsinchu (TW); Ka Man So, Hsinchu (TW)

(73) Assignee: Powerchip Semiconductor Manufacturing Corporation, Hsinchu (TW)

(21) Appl. No.: 18/784,949

(22) Filed: Jul. 26, 2024

(30) Foreign Application Priority Data
Jan. 8, 2024 (TW) 113100754

(51) Int. Cl. H01L 23/00; H01L 21/768; H01L 23/522; H01L 25/00; H01L 25/065

(52) U.S. Cl. CPC H01L 24/80; H01L 23/5226; H01L 24/08; H01L 24/09; H01L 25/0657; H01L 25/50; H01L 21/76804; H01L 2224/08146; H01L 2224/09181; H01L 2224/80895; H01L 2224/80896; H01L 2225/06544

(57) ABSTRACT

A semiconductor device includes a first stacked structure, a second stacked structure, a first vertical connector, and a second vertical connector. The first stacked structure includes a first stacked wafer and a first bonding layer. The first stacked wafer includes multiple first dielectric bonding interfaces. The second stacked structure includes a second stacked wafer and a second bonding layer. The second stacked wafer includes multiple second dielectric bonding interfaces. The first bonding layer is bonded and electrically connected to the second bonding layer, such that there is a hybrid bonding interface between the first stacked structure and the second stacked structure. The first vertical connector penetrates the first dielectric bonding interfaces and is electrically connected to the first bonding layer. The second vertical connector penetrates the second dielectric bonding interfaces and is electrically connected to the second bonding layer. A manufacturing method of the semiconductor device is also provided.

### CROSS-REFERENCE TO RELATED APPLICATION

This application claims the priority benefit of Taiwan application serial no. 113100754, filed on Jan. 8, 2024. The entirety of the above-mentioned patent application is hereby incorporated by reference herein and made a part of this specification.

### BACKGROUND

### Technical Field

The disclosure relates to a semiconductor device and a manufacturing method thereof.

### Description of Related Art

Currently, many direct bonding technologies have been used in semiconductor wafer stacked structures. However, the direct bonding technologies each have limitations in bonding ability, routing design, or manufacturing cost, thereby causing a bottleneck in the number of stacked layers that cannot be broken through. Therefore, how to meet the ever-increasing requirement for the number of stacked layers is indeed a challenge.

### SUMMARY

The disclosure provides a semiconductor device and a manufacturing method thereof, which can effectively increase the number of stacked layers.

A semiconductor device of the disclosure includes a first stacked structure, a second stacked structure, a first vertical connector, and a second vertical connector. The first stacked structure includes a first stacked wafer and a first bonding layer. The first stacked wafer includes multiple first dielectric bonding interfaces. The second stacked structure includes a second stacked wafer and a second bonding layer. The second stacked wafer includes multiple second dielectric bonding interfaces. The first bonding layer is bonded and electrically connected to the second bonding layer, such that there is a hybrid bonding interface between the first stacked structure and the second stacked structure. The first vertical connector penetrates the first dielectric bonding interfaces and is electrically connected to the first bonding layer. The second vertical connector penetrates the second dielectric bonding interfaces and is electrically connected to the second bonding layer.

In an embodiment of the disclosure, the first stacked structure includes multiple first element wafers, and one of the first dielectric bonding interfaces is located between two adjacent ones of the first element wafers. The second stacked structure includes multiple second element wafers, and one of the second dielectric bonding interfaces is located between adjacent two of the second element wafers.

In an embodiment of the disclosure, a number of the first element wafers is greater than or equal to three, and a number of the second element wafers is greater than or equal to three.

In an embodiment of the disclosure, each of the first dielectric bonding interfaces is composed of a first dielectric material, each of the second dielectric bonding interfaces is composed of a second dielectric material, and the hybrid bonding interface is composed of a third dielectric material and a conductive material.

In an embodiment of the disclosure, tapered contour directions of the first vertical connector and the second vertical connector are the same.

In an embodiment of the disclosure, the first vertical connector is tapered toward a direction away from the hybrid bonding interface, and the second vertical connector is tapered toward a direction close to the hybrid bonding interface.

In an embodiment of the disclosure, the first stacked structure includes a series connection layer, and two sides of the first vertical connector are respectively in direct contact with the series connection layer and the first bonding layer.

In an embodiment of the disclosure, at least two first vertical connectors are adjacently disposed on the series connection layer, and at least two second vertical connectors are correspondingly disposed on the at least two first vertical connectors.

In an embodiment of the disclosure, the semiconductor device further includes an external terminal disposed on the second vertical connector. The first vertical connector, the second vertical connector, and the external terminal are sequentially stacked and electrically connected to each other.

In an embodiment of the disclosure, a pad of the first bonding layer is in direct contact with a pad of the second bonding layer, and a dielectric layer of the first bonding layer is in direct contact with a dielectric layer of the second bonding layer.

In an embodiment of the disclosure, the first stacked structure further includes multiple first signal lines. The second stacked structure further includes multiple second signal lines. The first signal lines are electrically connected to the first vertical connector, and the second signal lines are electrically connected to the second vertical connector.

A manufacturing method of a semiconductor device of the disclosure includes at least the following steps. Forming a first stacked structure includes forming a first stacked wafer through multiple first direct bonding processes, such that the first stacked wafer includes multiple first dielectric bonding interfaces; and forming a first bonding layer on the first stacked wafer. Forming a second stacked structure includes forming a second stacked wafer through multiple second direct bonding processes, such that the second stacked wafer includes multiple second dielectric bonding interfaces; and forming a second bonding layer on the second stacked wafer. The first bonding layer and the second bonding layer are bonded and electrically connected through a third direct bonding process, such that a hybrid bonding interface is formed between the first bonding layer and the second bonding layer. A second vertical connector penetrating the second dielectric bonding interfaces and electrically connected to the second bonding layer is formed. The first vertical connector and the second vertical connector are electrically connected through the first bonding layer and the second bonding layer.

In an embodiment of the disclosure, the first direct bonding processes and the second direct bonding processes are oxide-oxide bonding processes, and the third direct bonding process is a hybrid bonding process.

In an embodiment of the disclosure, steps of each of the first direct bonding processes and each of the second direct bonding processes include bonding two element wafers, such that a top dielectric layer of one of the two element wafers is in direct contact with a bottom dielectric layer of other one of the two element wafers.

In an embodiment of the disclosure, a thinning process is executed between two adjacent ones in the first bonding processes and between two adjacent ones in the second bonding processes.

In an embodiment of the disclosure, the second vertical connector is formed after bonding the first bonding layer and the second bonding layer through the third direct bonding process.

In an embodiment of the disclosure, a number of the first direct bonding processes is greater than or equal to two, and a number of the second direct bonding processes is greater than or equal to two.

In an embodiment of the disclosure, the first direct bonding processes and the second direct bonding processes all do not include metal-to-metal bonding.

In an embodiment of the disclosure, the manufacturing method of the semiconductor device further includes forming an external terminal on the second vertical connector.

In an embodiment of the disclosure, the manufacturing method of the semiconductor device further includes: forming multiple first signal lines on the first stacked structure; and forming multiple second signal lines on the second stacked structure.

Based on the above, in the disclosure, the stacked wafers are connected through the hybrid bonding interface to provide the required bonding strength for the semiconductor device, and stacking is respectively performed in the stacked wafers through the dielectric bonding interfaces, and the layers are then conducted through the vertical connectors to simplify the routing density in the semiconductor device. In this way, a balance between bonding ability, routing design, and manufacturing cost can be obtained to effectively increase the number of stacked layers.

In order for the features and advantages of the disclosure to be more comprehensible, the following specific embodiments are described in detail in conjunction with the drawings.

### BRIEF DESCRIPTION OF THE DRAWINGS

FIG. 1A to FIG. 1L are schematic cross-sectional views of a manufacturing process of a semiconductor device according to an embodiment of the disclosure.

FIG. 2 is a schematic cross-sectional view of a semiconductor device according to another embodiment of the disclosure.

### DESCRIPTION OF THE EMBODIMENTS

In the following detailed description, for purposes of illustration and not limitation, exemplary embodiments disclosing specific details are set forth in order to provide a thorough understanding of various principles of the disclosure. However, it will be apparent to persons skilled in the art, having the benefit of the disclosure, that the disclosure may be practiced in other embodiments that depart from the specific details disclosed herein. In addition, descriptions of conventional devices, methods, and materials may be omitted so as not to obscure the various principles of the disclosure.

Exemplary embodiments of the disclosure will be fully described below with reference to the drawings, but the disclosure may be implemented according to many different forms and should not be construed as limited to the embodiments set forth herein. In the drawings, the sizes and thicknesses of various regions, parts, and layers are not drawn to actual scale for clarity. The same or similar reference numerals indicate the same or similar elements, which will not be repeated one by one in the following paragraphs.

It will be understood that although terms such as “first”, “second”, and “third” may be used herein to describe various elements, components, regions, layers, and/or parts, the elements, components, regions, layers, and/or parts should not be limited by the terms. The terms are only used to distinguish one element, component, region, layer, or part from another element, component, region, layer, or part.

Unless otherwise defined, all terms (including technical and scientific terms) used herein have the same meaning as commonly understood by persons skilled in the art to which the disclosure belongs.

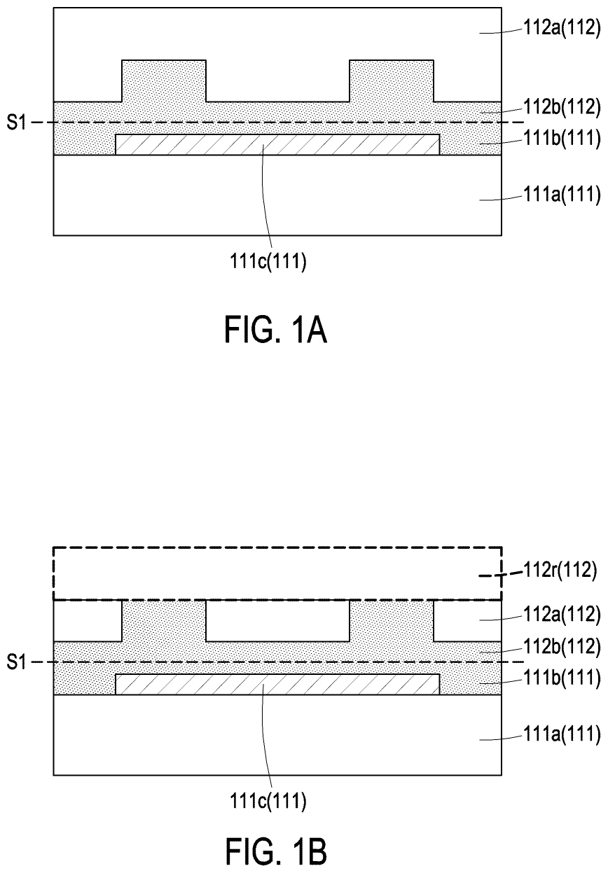

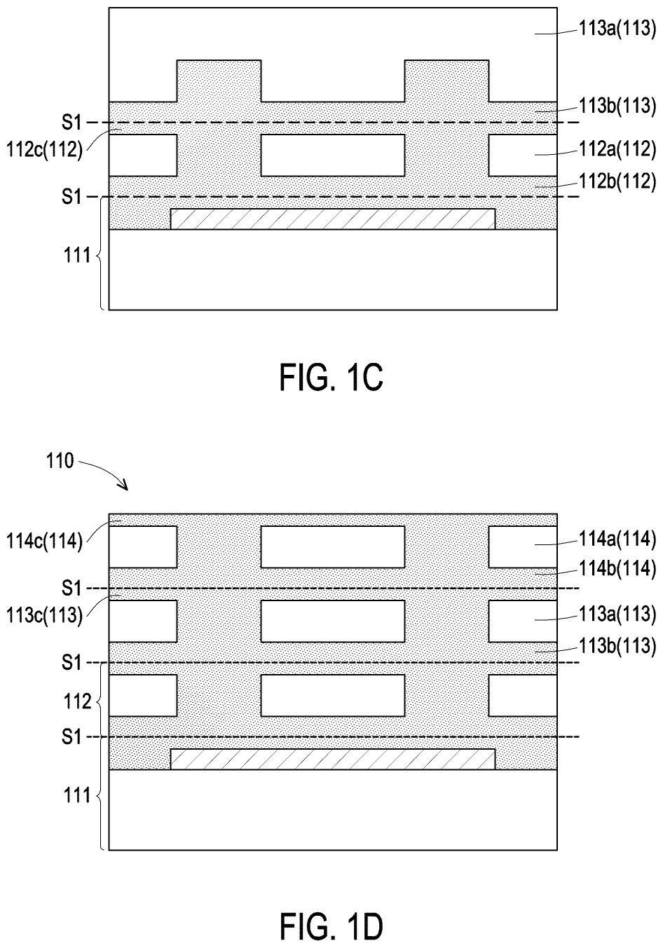

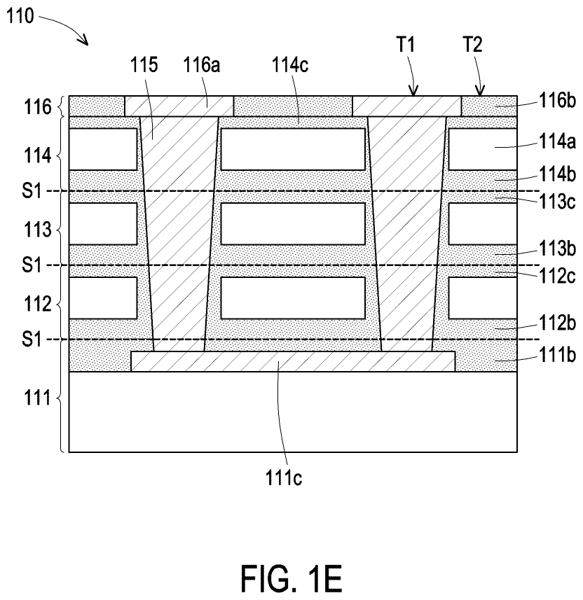

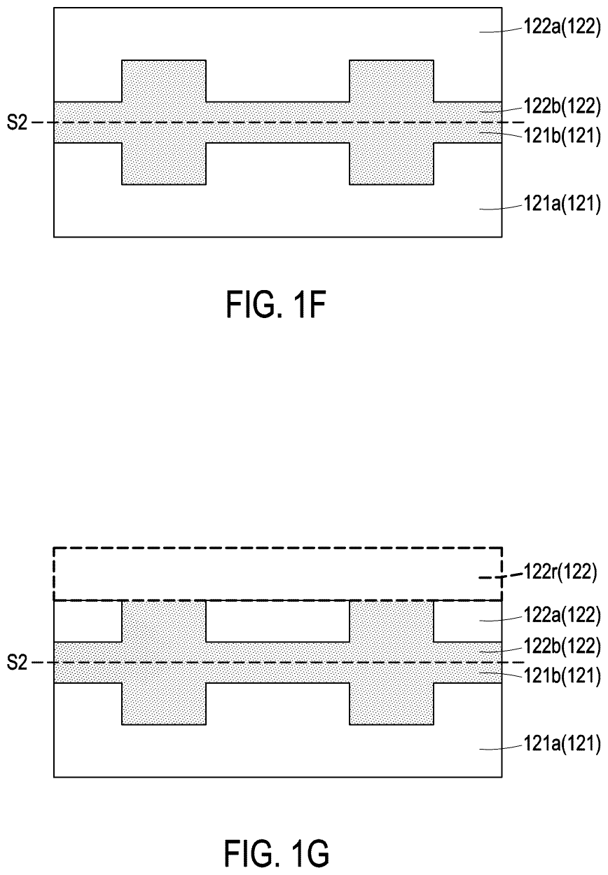

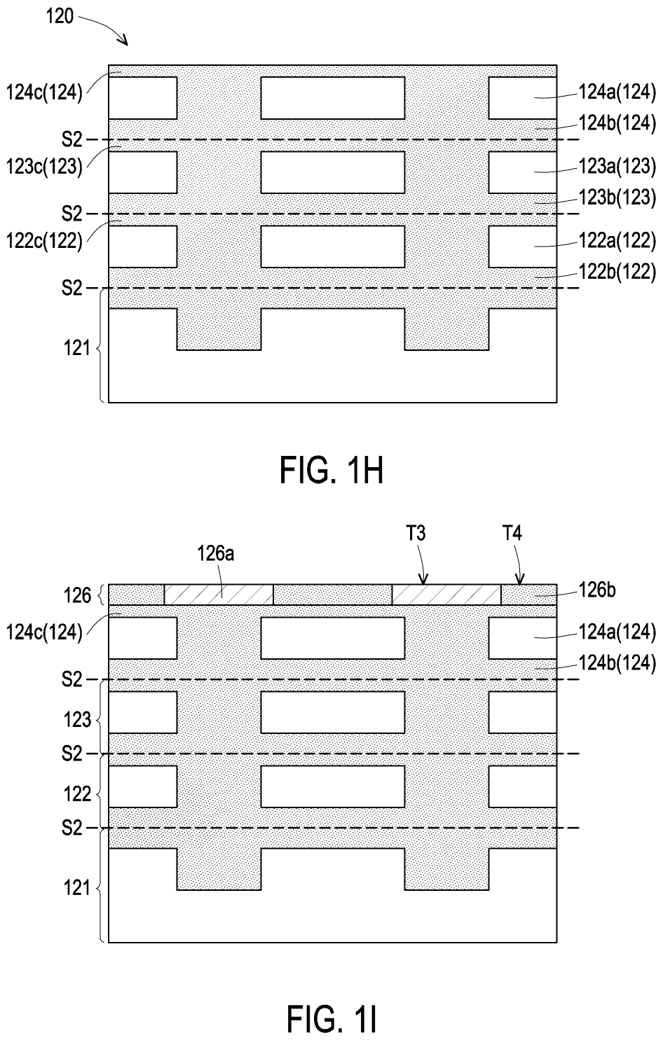

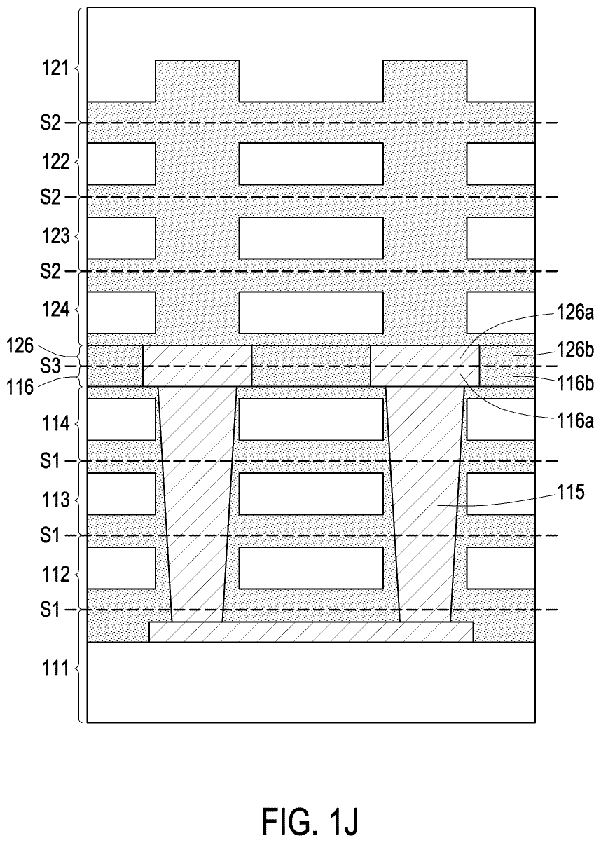

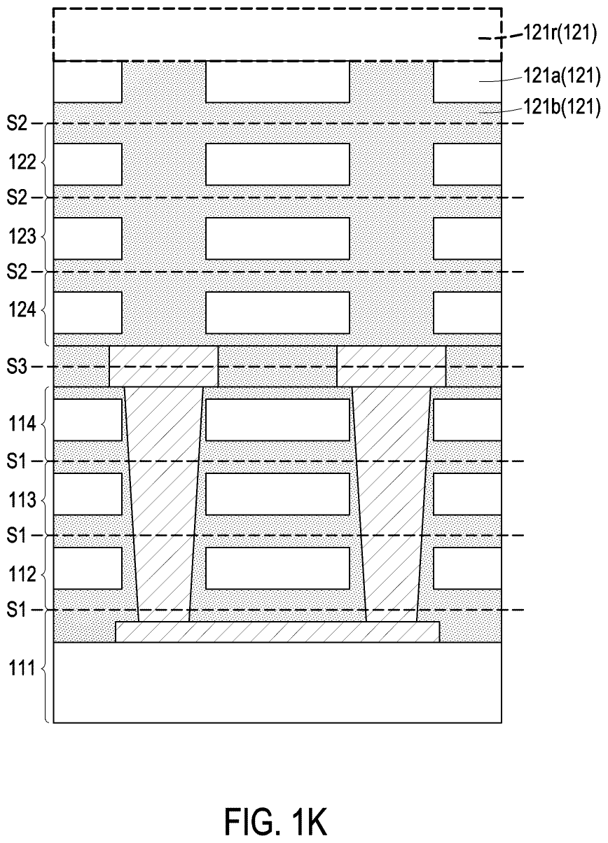

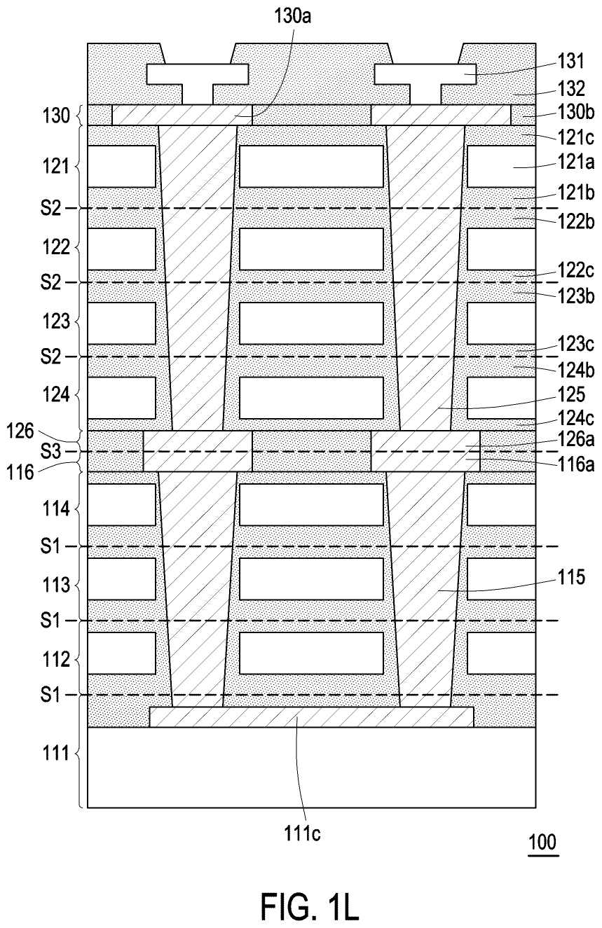

FIG. 1A to FIG. 1L are schematic cross-sectional views of a manufacturing process of a semiconductor device according to an embodiment of the disclosure.

Please refer to FIG. 1A to FIG. 1D. In the embodiment, a manufacturing process of a stacked wafer 110 may include at least the following steps. First, as shown in FIG. 1A, an element wafer 111 and an element wafer 112 are provided, and the element wafer 111 and the element wafer 112 are bonded through a direct bonding process to form a dielectric bonding interface S1, wherein the element wafer 111 may include a substrate 111a and a dielectric layer 111b disposed thereon, the element wafer 112 may include a substrate 112a and a dielectric layer 112b disposed thereon, and the dielectric layer 111b is in direct contact with the dielectric layer 112b.

In some embodiments, the direct bonding process is, for example, an oxide-oxide bonding (also referred to as fusion bonding) process. Therefore, the direct bonding process may not include metal-to-metal bonding, but the disclosure is not limited thereto.

In the embodiment, the element wafer 111 also includes a series connection layer 111c disposed on the substrate 111a and covered by the dielectric layer 111b to serve as a subsequent interconnection circuit. On the other hand, the substrate 112a of the element wafer 112 also has multiple grooves, and the dielectric layer 112b may fill the grooves and further extend to a surface of the substrate 112a to be bonded with the dielectric layer 111b. Here, the series connection layer 111c may be a redistribution layer (RDL) or the like.

Please refer to FIG. 1B. After the dielectric bonding interface S1 is formed, a thinning process is executed to remove a backside 112r of a part of the element wafer 112 (for example, a backside of the substrate 112a), wherein the thinning process may continue to thin toward the direction of the element wafer 111 until the dielectric layer 112b is exposed. Here, the thinning process is, for example, a chemical-mechanical polishing (CMP) process or the like.

Please refer to FIG. 1C. After the thinning process is executed, a dielectric layer 112c is formed on the substrate 112a to be used for another direct bonding process. Next, an element wafer 113 is provided. The element wafer 113 and the element wafer 112 are bonded through a direct bonding process similar to that described in FIG. 1A to form another dielectric bonding interface S1, wherein the element wafer 113 includes a substrate 113a and a dielectric layer 113b disposed thereon, and the dielectric layer 113b is in direct contact with the dielectric layer 112c. Here, the substrate 113a of the element wafer 113 also has multiple grooves, and the dielectric layer 113b may fill the grooves and further extend to a surface of the substrate 113a to be bonded with the dielectric layer 112c.

Please refer to FIG. 1D. The steps of FIG. 1B to FIG. 1C are repeated. In short, the thinning process may be executed to remove a backside (not shown) of a part of the element wafer 113. Next, a dielectric layer 113c is formed on the substrate 113a. Then, an element wafer 114 is provided. The element wafer 114 and the element wafer 113 are bonded through a direct bonding process similar to that described in FIG. 1A to form another dielectric bonding interface S1, wherein the element wafer 114 includes a substrate 114a and a dielectric layer 114b disposed thereon, and the dielectric layer 114b is in direct contact with the dielectric layer 113c. After the element wafer 114 is bonded, the thinning process (not shown) is executed again and a dielectric layer 114c is formed on the substrate 114a. The manufacturing of the stacked wafer 110 is roughly completed via the above steps.

Furthermore, after the above steps, the element wafer 112 may include the substrate 112a and the dielectric layers 112b and 112c that are interconnected and surround the substrate 112a, the element wafer 113 may include the substrate 113a and the dielectric layers 113b and 113c that are interconnected and surround the substrate 113a, and the element wafer 114 may include the substrate 114a and the dielectric layers 114b and 114c that are interconnected and surround the substrate 114a.

It should be noted that although FIG. 1A to FIG. 1D illustrate the direct bonding and stacking patterns of four element wafers (the element wafers 111, 112, 113, and 114), the disclosure does not limit the number of the direct bonding process and stacked first element wafers. Depending on actual design requirements, the above stacking step may be repeated multiple times to reach a predetermined number of stacked layers. For example, the predetermined number of stacked layers may be greater than or equal to three layers, so the number of element wafers of the stacked wafer 110 may be greater than or equal to three, and the number of the direct bonding process may be greater than or equal to two.

Please refer to FIG. 1E. After the predetermined number of stacked layers (four layers as shown in FIG. 1D) is stacked, a vertical connector 115 (which may be referred to as a first vertical connector) penetrating the dielectric bonding interface S1 may be formed. For example, in the embodiment, the vertical connector 115 may sequentially penetrate the dielectric layer 114c, the dielectric layer 114b, the dielectric layer 113c, the dielectric layer 113b, the dielectric layer 112c, the dielectric layer 112b, and the dielectric layer 111b from top to bottom and land on the series connection layer 111c. Therefore, the vertical connector 115 may be referred to as a through dielectric via (TDV), but the disclosure is not limited thereto.

Next, a bonding layer 116 is formed on the stacked wafer 110, wherein the stacked wafer 110 and the bonding layer 116 may be regarded as a stacked structure. Further, the bonding layer 116 includes multiple pads 116a and a dielectric layer 116b, wherein the dielectric layer 116b may surround the pad 116a, and a top surface T1 of the pad 116a and a top surface T2 of the dielectric layer 116b may be substantially coplanar.

In the embodiment, the vertical connector 115 is located between the series connection layer 111c and the bonding layer 116. For example, two sides of the vertical connector 115 are respectively in direct contact with the series connection layer 111c and the bonding layer 116, but the disclosure is not limited thereto.

It should be noted that the stacked structure and components included by the stacked structure may be referred to as “first”. For example, the stacked structure may be referred to as a first stacked structure, the stacked wafer 110 may be referred to as a first stacked wafer, and the element wafers 111, 112, 113, and 114 may be referred to as multiple first element wafers, the direct bonding process used may be referred to as a first direct bonding process, the dielectric bonding interface S1 may be referred to as a first dielectric bonding interface, and the bonding layer 116 may be referred to as a first bonding layer.

In addition, dielectric layers on two sides of the dielectric bonding interface S1 may be regarded as a top dielectric layer and a bottom dielectric layer of corresponding element wafers. For example, in FIG. 1A, the dielectric layer 111b and the dielectric layer 112b may be respectively regarded as the top dielectric layer of the element wafer 111 and the bottom dielectric layer of the element wafer 112, so the top dielectric layer of the element wafer 111 is in direct contact with the bottom dielectric layer of the element wafer 112.

Please refer to FIG. 1F to FIG. 1H. In the embodiment, a manufacturing process of a stacked wafer 120 may include at least the following steps. First, as shown in FIG. 1F, an element wafer 121 and an element wafer 122 are provided, and the element wafer 121 and the element wafer 122 are bonded through a direct bonding process to form a dielectric bonding interface S2, wherein the element wafer 121 may include a substrate 121a and a dielectric layer 121b disposed thereon, the element wafer 122 may include a substrate 122a and a dielectric layer 122b disposed thereon, and the dielectric layer 121b is in direct contact with the dielectric layer 122b.

In some embodiments, the direct bonding process is, for example, an oxide-oxide bonding (also referred to as fusion bonding) process. Therefore, the direct bonding process may not include metal-to-metal bonding, but the disclosure is not limited thereto.

In the embodiment, the substrates 121a and 122a of the element wafers 121 and 122 respectively have multiple grooves, and the dielectric layers 121b and 122b may respectively fill the grooves and respectively further extend to surfaces of the substrates 121a and 122a. Furthermore, since there may not be a series connection layer in the stacked wafer 120 (as shown in FIG. 1H), the element wafer 121 may be different from the element wafer 111, but the disclosure is not limited thereto.

Please refer to FIG. 1G. After the dielectric bonding interface S2 is formed, a thinning process is executed to remove a backside 122r of a part of the element wafer 122 (for example, a backside of the substrate 122a), wherein the thinning process may continue to thin toward the direction of the element wafer 121 until the dielectric layer 122b is exposed. Here, the thinning process is, for example, a chemical-mechanical polishing process or the like.

Please refer to FIG. 1H. After the thinning process is executed, a dielectric layer 122c is formed on the substrate 122a. Then, an element wafer 123 is provided. The element wafer 123 and the element wafer 122 are bonded through a direct bonding process similar to that described in FIG. 1F to form another dielectric bonding interface S2, wherein the element wafer 123 includes a substrate 123a and a dielectric layer 123b disposed thereon, and the dielectric layer 123b is in direct contact with the dielectric layer 122c.

The above steps are repeated. In short, the thinning process may be executed to remove a backside (not shown) of a part of the element wafer 123. Next, a dielectric layer 123c is formed on the substrate 123a. Then, an element wafer 124 is provided. The element wafer 124 and the element wafer 123 are bonded through a direct bonding process similar to that described in FIG. 1F to form another dielectric bonding interface S2, wherein the element wafer 124 includes a substrate 124a and a dielectric layer 124b disposed thereon, and the dielectric layer 124b is in direct contact with the dielectric layer 123c. The thinning process (not shown) continues to be executed and a dielectric layer 124c is formed on the substrate 124a. The manufacturing of the stacked wafer 120 is roughly completed via the above steps.

Furthermore, after the above steps, the element wafer 122 may include the substrate 122a and the dielectric layers 122b and 122c that are interconnected and surround the substrate 122a, the element wafer 123 may include the substrate 123a and the dielectric layers 123b and 123c that are interconnected and surround the substrate 123a, and the element wafer 124 may include the substrate 124a and the dielectric layers 124b and 124c that are interconnected and surround the substrate 124a.

Similar to the stacked wafer 110, depending on actual design requirements, the above stacking step may be repeated multiple times to reach a predetermined number of stacked layers. For example, the predetermined number of stacked layers may be greater than or equal to three layers, so the number of element wafers of the stacked wafer 120 may be greater than or equal to three, and the number of the direct bonding process may be greater than or equal to two. In addition, the number of element wafers in the stacked wafer 110 may be the same as or different from the number of element wafers in the stacked wafer 120.

Please refer to FIG. 1I. After the predetermined number of stacked layers (four layers as shown in FIG. 1H) is stacked, a bonding layer 126 is formed on the stacked wafer 120, and the stacked wafer 120 and the bonding layer 126 may be regarded as another stacked structure. Further, the bonding layer 126 includes multiple pads 126a and a dielectric layer 126b, wherein the dielectric layer 126b surrounds the pad 126a, and a top surface T3 of the pad 126a and a top surface T4 of the dielectric layer 126b may be substantially coplanar.

It should be noted that the stacked structure and components included by the stacked structure may be referred to as “second”. For example, the stacked structure may be referred to as a second stacked structure, the stacked wafer 120 may be referred to as a second stacked wafer, the element wafers 121, 122, 123, and 124 may be referred to as multiple second element wafers, the direct bonding process used may be referred to as a second direct bonding process, the dielectric bonding interface S2 may be referred to as a second dielectric bonding interface, and the bonding layer 126 may be referred to as a second bonding layer.

In addition, dielectric layers on two sides of the dielectric bonding interface S2 may be regarded as a top dielectric layer and a bottom dielectric layer of corresponding element wafers. For example, in FIG. 1F, the dielectric layer 121b and the dielectric layer 122b may be respectively regarded as the top dielectric layer of the element wafer element wafer 121 and the bottom dielectric layer of the element wafer 122, so the top dielectric layer of the element wafer 121 is in direct contact with the bottom dielectric layer of the element wafer 122.

In some embodiments, the type of any one of the element wafers 111, 112, 113, 114, 121, 122, 123, and 124 includes a DRAM wafer, a logic wafer, an integrated passive device (IPD), an IPD wafer, or the like, but the disclosure is not limited thereto. The element wafers 111, 112, 113, 114, 121, 122, 123, and 124 may be of any suitable type according to actual design requirements and may be the same or different.

Please refer to FIG. 1J. The bonding layer 116 and the bonding layer 126 are bonded and electrically connected through a direct bonding process, such that a hybrid bonding interface S3 is formed between the bonding layer 116 and the bonding layer 126.

In some embodiments, the direct bonding process is, for example, a hybrid bonding process, that is, the hybrid bonding interface and the above dielectric bonding interface may be formed using different process technologies. Therefore, the dielectric bonding interface formed in the hybrid bonding process is not the dielectric bonding interface described in the stacked wafer 110 or 120 of the disclosure, and metal-to-metal and dielectric-to-dielectric bonding interfaces (for example, the pad 116a of the bonding layer 116 is in direct contact with the pad 126a of the bonding layer 126, and the dielectric layer 116b of the bonding layer 116 is in direct contact with the dielectric layer 126b of the bonding layer 126) in the hybrid bonding interface are simultaneously formed instead of being formed by separate bonding.

For example, the dielectric bonding interfaces S1 and S2 are respectively composed of dielectric materials, and the hybrid bonding interface S3 is composed of a dielectric material and a conductive material, wherein the dielectric materials in the dielectric bonding interfaces S1 and S2 and the hybrid bonding interface S3 may be the same or different and are not limited by the disclosure.

Please refer to FIG. 1K. After the hybrid bonding interface S3 is formed, a thinning process is executed to remove a backside 121r of a part of the element wafer 121 (for example, a backside of the substrate 121a), wherein the thinning process may continue to thin toward the direction of the hybrid bonding interface S3 until the dielectric layer 121b is exposed. Here, the thinning process is, for example, a chemical-mechanical polishing process or the like.

Please refer to FIG. 1L. After the thinning process is executed, a dielectric layer 121c is formed on the substrate 121a. Next, a vertical connector 125 (which may be referred to as a second vertical connector) penetrating the dielectric bonding interface S2 is formed. The manufacturing of a semiconductor device 100 is roughly completed via the above steps. Accordingly, in the embodiment, the stacked wafers 110 and 120 are connected through the hybrid bonding interface S3 to provide the required bonding strength for the semiconductor device 100, and stacking is respectively performed in the stacked wafers 110 and 120 through the dielectric bonding interfaces S1 and S2, and the layers are then conducted through the vertical connectors 115 and 125 to simplify the routing density in the semiconductor device. In this way, a balance between bonding ability, routing design, and manufacturing cost can be obtained to effectively increase the number of stacked layers.

For example, when the number of stacked layers is greater than five, a large amount of wafers is consumed according to the conventional bonding technology of sequentially stacking from bottom to top, and if the hybrid bonding process is always used, the range that needs to be wired is too large. However, via the design of the embodiment, the number of stacked layers can be greater than or equal to six layers (by bonding the stacked wafer with three or more layers to another stacked wafer with three or more layers), which has a product competitive advantage.

In the embodiment, the vertical connector 125 may sequentially penetrate the dielectric layer 121c, the dielectric layer 121b, the dielectric layer 122b, the dielectric layer 122c, the dielectric layer 123b, the dielectric layer 123c, the dielectric layer 124b, and the dielectric layer 124c from top to bottom and land on the pad 126a. Therefore, the vertical connector 125 may also be referred to as a through dielectric via (TDV).

Furthermore, the vertical connector 115 and the vertical connector 125 are electrically connected through the bonding layer 116 and the bonding layer 126, and orthogonal projections of the vertical connector 115, the vertical connector 125, the bonding layer 116, and the bonding layer 126 on the element wafer 111 overlap with each other to form a vertical conductive path, which connects in series a top wafer to a bottom wafer in the semiconductor device 100.

In addition, since in the embodiment, the vertical connector 125 (which may be regarded as a via-last) is formed after the bonding layer 116 and the bonding layer 126 are bonded, tapered contour directions of the vertical connector 115 and the vertical connector 125 may be the same. For example, the vertical connector 115 is tapered toward a direction away from the hybrid bonding interface S3, and the vertical connector 125 is tapered toward a direction close to the hybrid bonding interface S3. In this way, improved operability can be achieved, but the disclosure is not limited thereto. Therefore, in an embodiment not shown, the vertical connector may be formed in the stacked wafer in the step of FIG. 1I. In this way, the tapered contour directions of the two vertical connectors are opposite to each other.

In the embodiment, after forming the vertical connector 125, an external layer 130 (including a circuit 130a and a dielectric layer 130b), an external terminal 131, and a protective layer 132 may be further sequentially formed, as shown in FIG. 1L, wherein the external layer 130 is optional. In an embodiment not shown, the external layer 130 may also be omitted, such that the external terminal 131 is directly disposed on the vertical connector 125. Here, the vertical connector 115, the vertical connector 125, and the external terminal 131 are sequentially stacked and electrically connected to each other. On the other hand, the protective layer 132 may have an opening to expose the external terminal 131.

The embodiment may also include at least two vertical connectors 115 and two vertical connectors 125. The two vertical connectors 115 are adjacently disposed on the series connection layer 111c, and the two vertical connectors 125 are correspondingly disposed on the two vertical connectors 115. Therefore, the vertical connector 115 and the vertical connector 125 stacked on one side may be electrically connected to the vertical connector 115 and the vertical connector 125 stacked on the other side through the series connection layer 111c to form a U-shaped conductive loop, but the disclosure is not limited thereto.

In some embodiments, the material of any of the substrates 111a, 112a, 113a, 114a, 121a, 122a, 123a, and 124a includes silicon or other suitable substrate materials, the material of any one of the dielectric layers 111b, 112b, 112c, 113b, 113c, 114b, 114c, 116b, 121b, 121c, 122b, 122c, 123b, 123c, 124b, 124c, 126b, and 130b and the protective layer 132 includes silicon oxide or other suitable dielectric materials, and the materials of the series connection layer 111c and the circuit 130a include copper or other suitable conductive materials. In addition, any one of the dielectric layers 111b, 112b, 112c, 113b, 113c, 114b, 114c, 116b, 121b, 121c, 122b, 122c, 123b, 123c, 124b, 124c, 126b, and 130b, the series connection layer 111c, the circuit 130a, the external terminal 131, and the protective layer 132 may be formed through chemical vapor deposition, atomic layer deposition, or other suitable deposition methods. Here, the structural layers referred to as the same may be formed using the same or similar materials and using the same or similar processes, which are not limited by the disclosure.

It must be noted here that the following embodiment continues to use the reference numerals and some content of the above embodiment, wherein the same or similar numerals are adopted to represent the same or similar elements, and the description of the same technical content is omitted. For the description of the omitted part, reference may be made to the above embodiment and will not be repeated in the following embodiment.

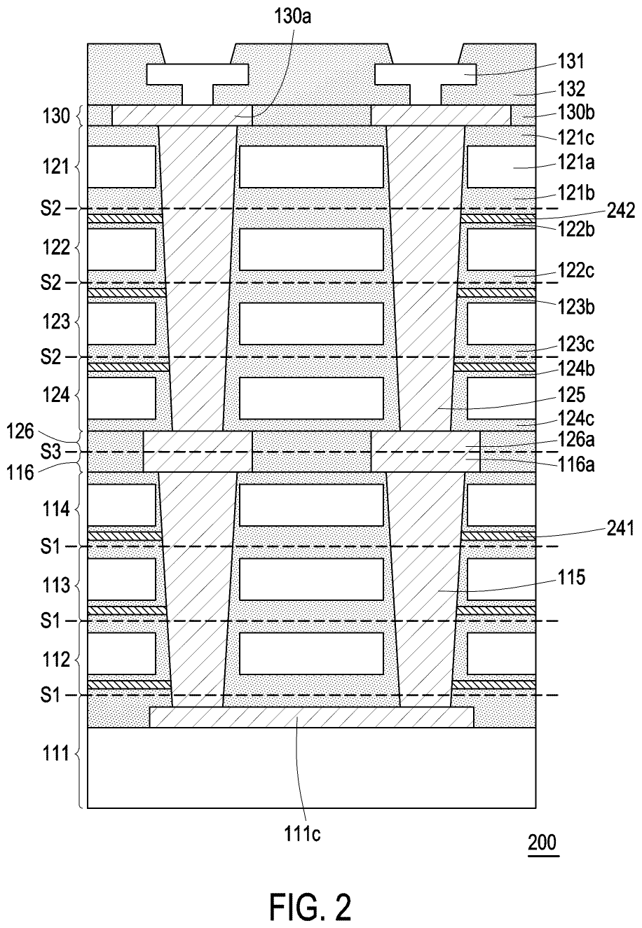

FIG. 2 is a schematic cross-sectional view of a semiconductor device according to another embodiment of the disclosure. Please refer to FIG. 2. Compared with the semiconductor device 100 of FIG. 1L, a semiconductor device 200 of the embodiment further forms multiple signal lines 241 in the first stacked structure and further forms multiple signal lines 242 in the second stacked structure, wherein the signal line 241 is electrically connected to the vertical connector 115, and the signal line 242 is electrically connected to the vertical connector 125. For example, the signal lines 241 of the embodiment may be in direct contact with the vertical connector 115, and the signal lines 242 may be in direct contact with the vertical connector 125. In this way, each layer only needs to arrange the signal lines connected to the same vertical connector in the layer (without the need to arrange for the vertical circuit), so a complex routing design in multiple layers may be omitted, but the disclosure is not limited thereto, and other suitable electrical connection manners may also be used in the semiconductor device.

In summary, in the disclosure, the stacked wafers are connected through the hybrid bonding interface to provide the required bonding strength for the semiconductor device, and stacking is respectively performed in the stacked wafers through the dielectric bonding interfaces, and the layers are then conducted through the vertical connectors to simplify the routing density in the semiconductor device. In this way, a balance between bonding ability, routing design, and manufacturing cost can be obtained to effectively increase the number of stacked layers.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A semiconductor device, comprising:
a first stacked structure, comprising a first stacked wafer and a first bonding layer, wherein the first stacked wafer comprises a plurality of first dielectric bonding interfaces;
a second stacked structure, comprising a second stacked wafer and a second bonding layer, wherein the second stacked wafer comprises a plurality of second dielectric bonding interfaces, and the first bonding layer is bonded and electrically connected to the second bonding layer, such that there is a hybrid bonding interface between the first stacked structure and the second stacked structure;
a first vertical connector, penetrating the first dielectric bonding interfaces and electrically connected to the first bonding layer; and
a second vertical connector, penetrating the second dielectric bonding interfaces and electrically connected to the second bonding layer.

2. The semiconductor device according to claim 1, wherein:
the first stacked structure comprises a plurality of first element wafers, and one of the first dielectric bonding interfaces is located between two adjacent ones of the first element wafers; and
the second stacked structure comprises a plurality of second element wafers, and one of the second dielectric bonding interfaces is located between two adjacent ones of the second element wafers.

3. The semiconductor device according to claim 2, wherein a number of the first element wafers is greater than or equal to three, and a number of the second element wafers is greater than or equal to three.

4. The semiconductor device according to claim 1, wherein each of the first dielectric bonding interfaces is composed of a first dielectric material, each of the second dielectric bonding interfaces is composed of a second dielectric material, and the hybrid bonding interface is composed of a third dielectric material and a conductive material.

5. The semiconductor device according to claim 1, wherein tapered contour directions of the first vertical connector and the second vertical connector are the same.

6. The semiconductor device according to claim 5, wherein the first vertical connector is tapered toward a direction away from the hybrid bonding interface, and the second vertical connector is tapered toward a direction close to the hybrid bonding interface.

7. The semiconductor device according to claim 1, wherein the first stacked structure comprises a series connection layer, and two sides of the first vertical connector are respectively in direct contact with the series connection layer and the first bonding layer.

8. The semiconductor device according to claim 7, wherein at least two first vertical connectors are adjacently disposed on the series connection layer, and at least two second vertical connectors are correspondingly disposed on the at least two first vertical connectors.

9. The semiconductor device according to claim 1, further comprising an external terminal disposed on the second vertical connector, wherein the first vertical connector, the second vertical connector, and the external terminal are sequentially stacked and electrically connected to each other.

10. The semiconductor device according to claim 1, wherein a pad of the first bonding layer is in direct contact with a pad of the second bonding layer, and a dielectric layer of the first bonding layer is in direct contact with a dielectric layer of the second bonding layer.

11. The semiconductor device according to claim 1, wherein the first stacked structure further comprises a plurality of first signal lines, the second stacked structure further comprises a plurality of second signal lines, the first signal lines are electrically connected to the first vertical connector, and the second signal lines are electrically connected to the second vertical connector.

12. A manufacturing method of a semiconductor device, comprising:
forming a first stacked structure, comprising:
forming a first stacked wafer through a plurality of first direct bonding processes, such that the first stacked wafer comprises a plurality of first dielectric bonding interfaces; and
forming a first bonding layer on the first stacked wafer;
forming a first vertical connector penetrating the first dielectric bonding interfaces;
forming a second stacked structure, comprising:
forming a second stacked wafer through a plurality of second direct bonding processes, such that the second stacked wafer comprises a plurality of second dielectric bonding interfaces; and
forming a second bonding layer on the second stacked wafer;
bonding and electrically connecting the first bonding layer and the second bonding layer through a third direct bonding process, such that a hybrid bonding interface is formed between the first bonding layer and the second bonding layer; and
forming a second vertical connector penetrating the second dielectric bonding interfaces and electrically connected to the second bonding layer, wherein the first vertical connector and the second vertical connector are electrically connected through the first bonding layer and the second bonding layer.

13. The manufacturing method of the semiconductor device according to claim 12, wherein the first direct bonding processes and the second direct bonding processes are oxide-oxide bonding processes, and the third direct bonding process is a hybrid bonding process.

14. The manufacturing method of the semiconductor device according to claim 12, wherein steps of each of the first direct bonding processes and each of the second direct bonding processes both comprise bonding two element wafers, such that a top dielectric layer of one of the two element wafers is in direct contact with a bottom dielectric layer of other one of the two element wafers.

15. The manufacturing method of the semiconductor device according to claim 12, wherein a thinning process is executed between two adjacent ones in the first bonding processes and between two adjacent ones in the second bonding processes.

16. The manufacturing method of the semiconductor device according to claim 12, wherein the second vertical connector is formed after bonding the first bonding layer and the second bonding layer through the third direct bonding process.

17. The manufacturing method of the semiconductor device according to claim 12, wherein a number of the first direct bonding processes is greater than or equal to two, and a number of the second direct bonding processes is greater than or equal to two.

18. The manufacturing method of the semiconductor device according to claim 12, wherein the first direct bonding processes and the second direct bonding processes all do not comprise metal-to-metal bonding.

19. The manufacturing method of the semiconductor device according to claim 12, further comprising forming an external terminal on the second vertical connector.

20. The manufacturing method of the semiconductor device according to claim 12, further comprising:
forming a plurality of first signal lines on the first stacked structure; and
forming a plurality of second signal lines on the second stacked structure.
